(19) United States
(12) Patent Application Publication
(10) Pub. No.: US 2015/0214929 A1
(43) Pub. Date: Jul. 30, 2015

(54) GATE DRIVER INCLUDING LEVEL SHIFTER AND METHOD FOR DRIVING THE SAME

(71) Applicant: SAMSUNG ELECTRO-MECHANICS CO., LTD., Suwon-Si (KR)

(72) Inventors: Soo Woong LEE, Seoul (KR); Joong Ho CHOI, Seongnam-si (KR)

(21) Appl. No.: 14/608,110

(22) Filed: Jan. 28, 2015

(30) Foreign Application Priority Data
Jan. 29, 2014 (KR) 10-2014-0011224

(51) Int. Cl. H03K 3/012; H03K 17/687

(52) U.S. Cl. CPC H03K 3/012; H03K 17/687

(57) ABSTRACT

A gate driver comprises a level shifter outputting first and second signals; an output switch unit causing a first current flow in an output terminal by a voltage of the first signal in a first section of the driver to charge the output terminal, causing a second current flow by a voltage of the second signal in a second section, and discharging the output terminal depending on the second current. A current sensing unit causes a sensing current flow depending on the voltage of the second signal in the second section and outputting a preset voltage depending on the flow of the sensing current. A feedback unit causes the voltage of the second signal to attain at least a preset level in the second section depending on the preset voltage.

### CROSS REFERENCE(S) TO RELATED APPLICATIONS

This application claims the foreign priority benefit under 35 U.S.C. Section 119 of Korean Patent Application Serial No. 10-2014-0011224, entitled “Gate Driver Including Level Shifter And Method For Driving The Same” filed on Jan. 29, 2014, which is hereby incorporated by reference in its entirety into this application.

### BACKGROUND

1. Technical Field

The present subject matter relates to a gate driver including a level shifter and a method for driving the same.

2. Description of the Related Art

Generally, a gate driver may stably turn on/turn off a power switch. To this end, the gate driver may be driven with a high voltage by using a control signal having a low voltage level using a level shifter. However, a load terminal which is connected to the gate driver may include a capacitor, and a constant current may flow in the gate driver while a capacitor is charged/discharged. When the constant current flows in the gate driver, the gate driver may unnecessarily consume power. In particular, when the gate driver is driven with a high voltage, the gate driver may consume a large amount of power due to the constant current.

Further, as the interest in environmental issues is recently increased, most electronic products are designed to have an energy saving function, and therefore a gate driver which consumes low power may be required.

### SUMMARY

An object of the described subject matter is to provide a gate driver including a level shifter capable of reducing power consumption by reducing a generation of constant current, and a method for driving the same.

According to an exemplary embodiment, there is provided a gate driver, including a level shifter outputting a first signal and a second signal; an output switch unit causing flow of a first current to an output terminal by a voltage of the first signal in a first section to charge the output terminal, causing flow of a second current by a voltage of the second signal in a second section, and discharging the output terminal depending on the second current; a current sensing unit providing flow of a sensing current depending on the voltage of the second signal in the second section and outputting a preset voltage depending on the flow of the sensing current; and a feedback unit causing the voltage of the second signal to be at or above a preset level in the second section depending on the preset voltage.

According to another exemplary embodiment, there is provided a method for driving a gate driver, including causing flow of a first current to an output terminal in a first section to charge the output terminal; cutting off the first current in a second section and causing flow of a second current and a sensing current; discharging the output terminal by the second current; and reducing an amount of the second current depending on a preset voltage level and generating the preset voltage level by the flow of the sensing current.

### BRIEF DESCRIPTION OF THE DRAWINGS

FIG. 1 is a circuit diagram illustrating a gate driver including a level shifter according to a first exemplary embodiment of the present invention.

FIG. 2 is a timing diagram illustrating an operation of the gate driver illustrated in FIG. 1.

FIG. 3 is a circuit diagram illustrating a gate driver including a level shifter according to a second exemplary embodiment of the present invention.

FIG. 4 is a timing diagram illustrating an operation of the gate driver illustrated in FIG. 3.

FIG. 5 is a block diagram illustrating connection of the gate driver illustrated in FIG. 3 to a power switch.

FIG. 6 is a timing diagram illustrating the operation of the gate driver and the power switch.

FIG. 7 is a flow chart illustrating a method for driving a gate driver including a level shifter shown in FIG. 3.

### DESCRIPTION OF THE PREFERRED EMBODIMENTS

Matters of function and configuration of a gate driver and a method for driving the same according to an exemplary embodiment of the present invention to achieve the above object will be clearly obvious by the following detailed description with reference to the drawings which illustrate exemplary embodiments of the present invention.

Further, when it is determined that the detailed description of the known art related to the present invention may obscure the gist of the present invention, the detailed description thereof will be omitted. In the description, the terms “first”, “second”, and so on are used to distinguish one element from another element, and the elements are not defined by the above terms.

Embodiments of the present invention will be described in detail with reference to the accompanying drawings. These embodiments will be described in detail for those skilled in the art in order to practice the present invention. It should be appreciated that various embodiments of the present invention are different but do not have to be exclusive. For example, specific shapes, configurations, and characteristics described in an embodiment of the present invention may be implemented in another embodiment without departing from the spirit and the scope of the present invention. In addition, it should be understood that position or arrangement of individual components in each disclosed embodiment may be changed without departing from the spirit and the scope of the present invention. Therefore, a detailed description described below should not be construed as being restrictive. In addition, the scope of the present invention is defined only by the accompanying claims and their equivalents if appropriate. Similar reference numerals will be used to describe the same or similar functions throughout the accompanying drawings.

Hereinafter, exemplary embodiments of the present invention will be described in detail with reference to the accompanying drawings so that those skilled in the art may easily practice the present invention.

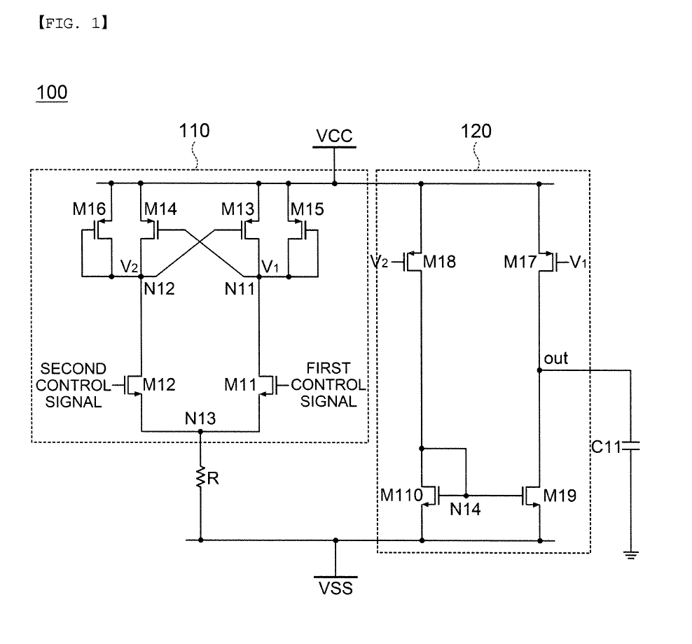

FIG. 1 is a circuit diagram illustrating a gate driver including a level shifter according to a first exemplary embodiment of the present invention.

Referring to FIG. 1, a gate driver 100 according to an exemplary embodiment of the present invention may include a level shifter 110 and an output switch unit 120.

The level shifter 110 may drive a signal having a high voltage using a control signal having a low voltage level. To this end, the level shifter 110 may be connected between a first power source Vcc and a second power source Vss and may output a first signal V1 or a second signal V2 which has a voltage of the first power source Vcc in different sections by using a first control signal and a second control signal which have a low voltage.

Further, the level shifter 110 may include a first transistor M11, a second transistor M12, a third transistor M13, a fourth transistor M14, a fifth transistor M15, and a sixth transistor M16. A first electrode of the first transistor M11 may be connected to a first node N11 and a second electrode thereof may be connected to the second power source Vss through a third node N13. Further, a gate electrode of the first transistor M11 may receive the first control signal. A first electrode of the second transistor M12 may be connected to a second node N12 and a second electrode thereof may be connected to the second power source Vss through the third node N13. Further, a gate electrode of the second transistor M12 may receive the second control signal. A first electrode of the third transistor M13 may be connected to the first power source Vcc and a second electrode thereof may be connected to the first node N11. Further, a gate electrode of the third transistor M13 may be connected to the second node N12. A first electrode of the fourth transistor M14 may be connected to the first power source Vcc and a second electrode thereof may be connected to the second node N12. Further, a gate electrode of the fourth transistor M14 may be connected to the first node N11. A first electrode of the fifth transistor M15 may be connected to the first power source Vcc and a second electrode and a gate electrode thereof may be connected to the first node N11. Therefore, the fifth transistor M15 may be diode connected. Further, a first electrode of the sixth transistor M16 may be connected to the first power source Vcc and a second electrode and a gate electrode thereof may be connected to the second node N12. Therefore, the sixth transistor M16 may be diode connected.

The output switch unit 120 performs a switching operation depending on a voltage of the first node N11 and the second node N12 of the level shifter 110 to be able to charge or discharge a capacitor C11 which is connected to an output terminal out. The capacitor C11 may be a capacitor component which is included in a load connected to the output terminal out. To this end, the output switch unit 120 is connected between the first power source Vcc and the second power source Vss and may charge or discharge the output terminal out depending on the voltage of the first node N11 or the second node N12 of the level shift 110. Herein, the voltages of the first node N11 or the second node N12 may each be the first signal V1 output from the first node N11 or the second signal V2 output from the second node N12.

Further, the output switch unit 120 may include a seventh transistor M17, an eighth transistor M18, a ninth transistor M19, and a tenth transistor M110. A first electrode of the seventh transistor M17 may be connected to the first power source Vcc and a second electrode thereof may be connected to the output terminal out. Further, a gate electrode of the seventh transistor M17 is connected to the first node N11 and thus may receive a first signal. A first electrode of the eighth transistor M18 may be connected to the first power source Vcc and a second electrode thereof may be connected to the first electrode of the tenth transistor M110. Further, a gate electrode of the eighth transistor M18 is connected to the second node N12 and thus may receive a second signal. A first electrode of the ninth transistor M19 may be connected to the output terminal out and a second electrode thereof may be connected to the second power source Vss. Further, the gate electrode of the ninth transistor M19 may be connected to a gate electrode of the tenth transistor M110. Further, a first electrode of the tenth transistor M110 may be connected to the second electrode of the eighth transistor M18 and a second electrode of tenth transistor M110 may be connected to the second power source Vss. Further, the gate electrode of the tenth transistor M110 may be connected to a gate electrode of the ninth transistor M19. Further, the first electrode and the gate electrode of the tenth transistor M110 are connected to each other, and thus the tenth transistor M110 may be diode connected. Therefore, a current flowing in the ninth transistor M19 is mirrored with a current flowing in the tenth transistor M110, and thus when a current flows in the tenth transistor M110, a current may also flow in the ninth transistor M19.

Here, the first power source Vcc may have a preset voltage level and the second power source Vss may have a voltage level lower than that of the first power source Vcc. Further, the first power source Vcc may be 7V and the second power source Vss may be a ground.

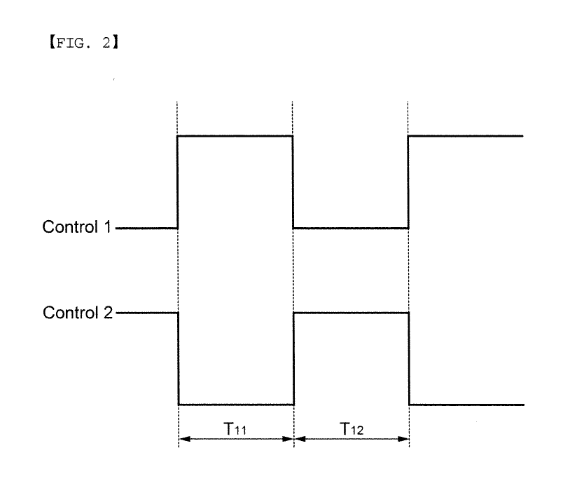

FIG. 2 is a timing diagram illustrating an operation of the gate driver illustrated in FIG. 1.

Referring to FIG. 2, the gate driver 100 may receive a first control signal control1 and a second control signal control2. The first control signal control1 may be in a high state in a first section T11 and a low state in a second section T12. Further, the second control signal control2 may be in a low state in the first section T11 and a high state in the second section T12. Further, the first control signal control1 and the second control signal control2 may each repeat the high state and the low state. FIG. 2 illustrates that lengths of the first section T11 and the second section T12 are the same, but the exemplary embodiment of the present invention is not limited thereto.

Further, in the first section T11, the first control signal control1 may be in the high state and the second control signal control2 may be in the low state. The first transistor M11 may be turned on and the second transistor M12 may be turned off, by the first control signal control1 and the second control signal control2. When the first transistor M11 is turned on, the first node N11 is connected to the second power source Vss and thus the first node N11 may be in the low state. Further, when the first node N11 is in the low state, the gate electrode of the fourth transistor M14 is in the low state and thus the fourth transistor M14 may be turned on. Further, the gate electrode of the fifth transistor M15 is applied with a voltage in a low state by the first node N11 and thus the fifth transistor M15 may be turned on. Further, when the fourth transistor M14 is turned on, the second transistor M12 is turned off and thus the second node N12 may be in the high state. When the second node N12 is in the high state, the gate electrode of the third transistor M13 is in the high state and thus the third transistor M13 may be turned off. Further, the gate electrode of the sixth transistor M16 is in the high state and thus the sixth transistor M16 may be turned off. That is, in the first section T11, the first node N11 of the level shifter 110 may be in the low state and the second node N12 thereof may be in the high state.

Further, in the second section T11, the first control signal control1 may be in the low state and the second control signal control2 may be in the high state. When the first control signal control1 is in the low state and the second control signal control2 is in the high state, the first transistor M11 may be turned off and the second transistor M12 may be turned on. When the second transistor M12 is turned on, the second node N12 may be in the low state. Further, when the second node N12 is in the low state, the gate electrode of the third transistor M13 is in the low state and thus the third transistor M13 may be turned on. When the third transistor M13 is turned on, since the first transistor M11 is turned off, the first node N11 may be in the high state. Further, since the first node N11 is in the high state, the gate electrode of the fourth transistor M14 is applied with a voltage in a high state and thus the fourth transistor M14 may be turned off. Further, since the first node N11 is in the high state, the gate electrode of the fifth transistor M15 is in the high state and thus the fifth transistor M15 may be turned off. The gate electrode of the sixth transistor M16 is in the low state and thus sixth transistor M16 may be turned on. That is, in the second section T12, the first node N11 of the level shifter 110 may be in the high state and the second node N12 thereof may be in the low state.

Further, in the first section T11, the first node N11 is in the low state and the second node N12 is in the high state, such that the seventh transistor M17 of the output switch unit 120 may be turned on and the eighth transistor M18 thereof may be turned off. Therefore, a current may flow from the first power source Vcc to the output terminal out, and thus the capacitor C11 connected to the output terminal out may be charged. Further, in the second section T12, the first node N11 may be in the high state and the second node N12 is in the low state, such that the seventh transistor M17 may be turned off and the eighth transistor M18 thereof may be turned on. Therefore, the first power source Vcc is not connected to the output terminal out and thus a current may no longer flow. Further, when the eighth transistor M18 is in a turn on state, a current may flow from the first power source Vcc to the second power source Vss through the eighth transistor M18. In this case, the first electrode and the gate electrode of the tenth transistor M110 have the same voltage level, such that the tenth transistor M110 may be turned on and a current may flow from the first power source Vcc to the second power source Vss. Further, since the ninth transistor M19 has a mirroring relationship with the tenth transistor M110, when the tenth transistor M110 is turned on and thus a current flows, the ninth transistor M19 is also turned on and thus a current may flow. Therefore, the current charged in the capacitor C11 may be discharged through the ninth transistor M19. For this reason, the first section T11 may be termed a charging section and the second section T12 may be termed a discharging section.

In this case, in the second section T12, the eighth transistor M18 and the tenth transistor M110 are turned on and thus a current may continuously flow in a direction from the first power source Vcc to the second power source Vss.

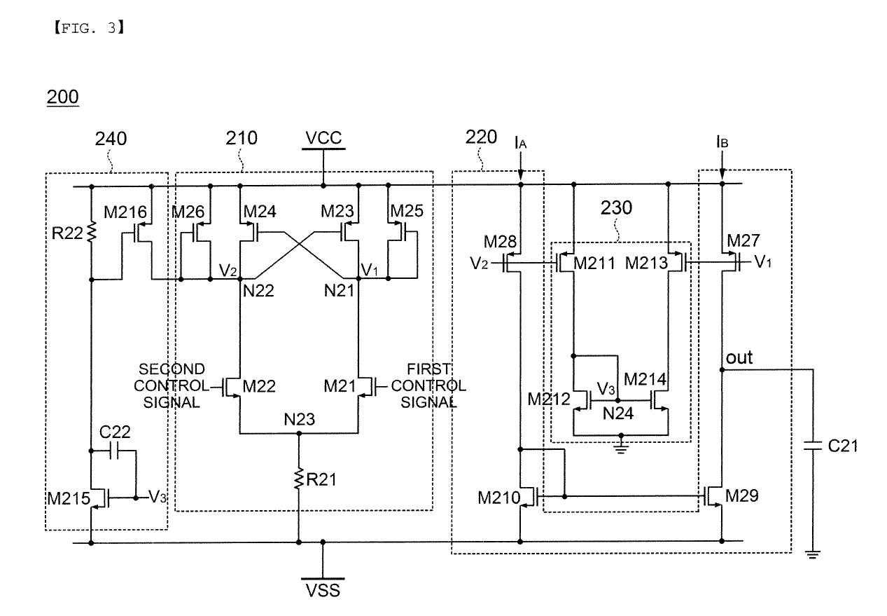

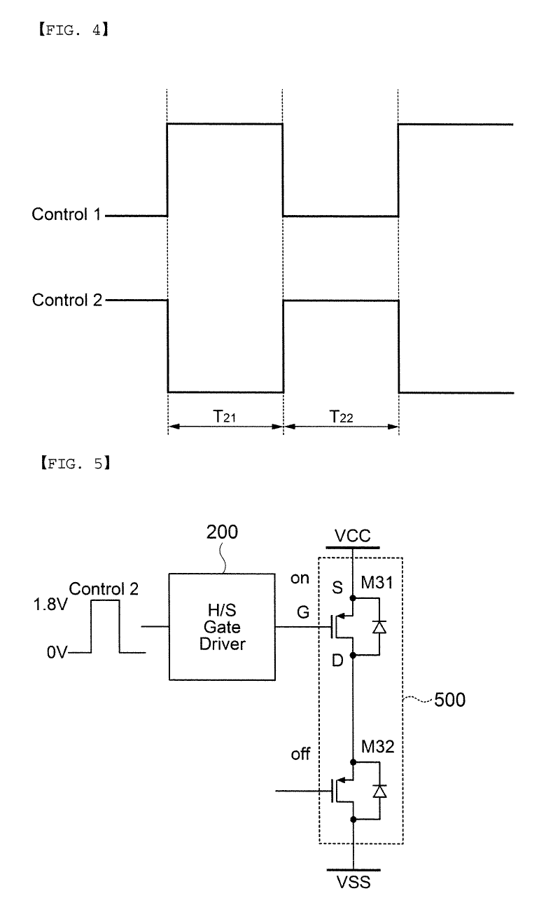

FIG. 3 is a circuit diagram illustrating a gate driver including a level shifter according to a second exemplary embodiment of the present invention and FIG. 4 is a timing diagram illustrating an operation of the gate driver illustrated in FIG. 3.

Referring to FIGS. 3 and 4, a gate driver 200 according to an exemplary embodiment of the present invention may include a level shifter 210 which outputs a first signal V1 and a second signal V2, an output switch unit 220 which causes a first current I_{B} to flow in an output terminal by a voltage of the first signal V1 in a first section T21 to charge the output terminal out, a . a second current I_{A} to flow by a voltage of a second signal in a second section T22, and discharges the output terminal out depending on the second current IA, a current sensing unit 230 which outputs a preset voltage depending on flow of sensing current depending on the voltage of the second signal in the second section T22, and a feedback unit 240 which drives the voltage of the second signal to a predetermined level or more in the second section T22 depending on the preset voltage.

The level shifter 210 may drive a signal having a high voltage using a control signal having a low voltage level. To this end, the level shifter 210 may be connected between a first power source Vcc and a second power source Vss and may output the first signal V1 having the voltage of the first power source Vcc or the second signal V2 which has a voltage lower than the voltage of the first power source Vcc based on a first control signal control1 and a second control signal control2.

Further, the level shifter 210 may include a first transistor M21, a second transistor M22, a third transistor M23, a fourth transistor M24, a fifth transistor M25, and a sixth transistor M26. A first electrode of the first transistor M21 may be connected to a first node N21 and a second electrode of the first transistor M21 may be connected to the second power source Vss through the third node N23. Further, a gate electrode of the first transistor M21 may receive the first control signal control1. A first electrode of the second transistor M22 may be connected to a second node N22 and a second electrode of the second transistor M22 may be connected to the second power source Vss through the third node N23. Further, a gate electrode of the second transistor M22 may receive the first control signal control2. A first electrode of the third transistor M23 may be connected to the first power source Vcc and a second electrode thereof may be connected to the first node N21. Further, a gate electrode of the third transistor M23 may be connected to the second node N22. A first electrode of the fourth transistor M24 may be connected to the first power source Vcc and a second electrode thereof may be connected to the second node N22. Further, a gate electrode of the fourth transistor M24 may be connected to the first node N12. A first electrode of the fifth transistor M25 may be connected to the first power source Vcc and a second electrode and a gate electrode thereof may be connected to the first node N21 and thus the fifth transistor M25 may be diode connected. Further, a first electrode of the sixth transistor M26 may be connected to the first power source Vcc and a second electrode and a gate electrode of the sixth transistor M26 may be connected to the second node N22 and thus the sixth transistor M26 may be diode-connected.

The output switch unit 220 performs a switching operation depending on the voltage of the first node N21 and the second node N22 of the level shifter 210 to be able to charge or discharge a first capacitor C21 which is connected to the output terminal out. The first capacitor C21 may be a capacitor component which is included in a load. Further, the output switch unit 220 is connected between the first power source Vcc and the second power source Vss and may cause a first current or a second current to flow in response to the first signal V1 or the second signal V2 output through the first node N21 or the second node N22 of the level shifter 210 to be able to charge or discharge the output terminal out.

Further, the output switch unit 220 may include a seventh transistor M27, an eighth transistor M28, a ninth transistor M29, and a tenth transistor M210. A first electrode of the seventh transistor M27 may be connected to the first power source Vcc and a second electrode of the seventh transistor M27 may be connected to the output terminal out. Further, a gate electrode of the seventh transistor M27 is connected to the first node N21 of the level shifter 210 and thus may receive the first signal V1. A first electrode of the eighth transistor M28 may be connected to the first power source Vcc and a second electrode of the eighth transistor M28 may be connected to the first electrode of the tenth transistor M210. Further, a gate electrode of the eighth transistor M28 is connected to the second node N22 of the level shifter 210 and thus may receive the second signal V2. A first electrode of the ninth transistor M29 may be connected to the output terminal out and a second electrode of the ninth transistor M29 may be connected to the second power source Vss. Further, the gate electrode of the ninth transistor M29 may be connected to a gate electrode of the tenth transistor M210. Further, a first electrode of the tenth transistor M210 may be connected to the second electrode of the eighth transistor M28 and a second electrode the tenth transistor M210 may be connected to the second power source Vss. Further, the gate electrode of the tenth transistor M210 may be connected to a gate electrode of the ninth transistor M29. Further, the first electrode and the gate electrode of the tenth transistor M210 are connected to each other, and thus the tenth transistor M210 may be diode-connected.

The current sensing unit 230 may output a preset voltage in response to the flow of sensing current. To this end, the current sensing unit 230 may be connected between the first power source Vcc and the second power source Vss, and when the second current I_{A} flows in the second section T22, the output switch unit 220 also causes the sensing current to flow in the current sensing unit 230 and may generate the preset voltage in response thereto. The preset voltage is not limited to a specific voltage and may be voltage which is generated when flow of the sensing current is generated.

Further, the current sensing unit 230 may include an eleventh transistor M211 and a twelfth transistor M212. The first electrode of the eleventh transistor M211 may be connected to the eighth transistor M28 of the output switch unit 220 and the second electrode thereof may be connected to the first electrode of the twelfth transistor M212. Further, a gate electrode of the eleventh transistor M211 may be connected to the second node N22 of the level shifter 210. A first electrode of the twelfth transistor M212 may be connected to the second electrode of the eleventh transistor M211 and a second electrode thereof may be connected to the second power source Vss. Further, the gate electrode of the twelfth transistor M212 is connected to the gate electrode of the fourteenth transistor M214 and the second electrode of the eleventh transistor M11 and thus the twelfth transistor M212 may be diode-connected. Therefore, when the eleventh transistor M211 is turned on, the twelfth transistor M212 is diode-connected and thus a current corresponding to the second node N22 may flow in the current sensing unit 230.

According to the exemplary embodiment of the present invention, the current sensing unit 230 may further include a thirteenth transistor M213 and a fourteenth transistor M214. The first electrode of the thirteenth transistor M213 may be connected to the first electrode of the seventh transistor M27 of the output switch unit 220 and the second electrode thereof may be connected to the first electrode of the fourteenth transistor M214. Further, a gate electrode of the thirteenth transistor M213 may be connected to the first node N21 of the level shifter 210. A first electrode of the fourteenth transistor M214 may be connected to the second electrode of the thirteenth transistor M213 and a second electrode of the fourteenth transistor M214 may be connected to the second power source Vss. Further, the gate electrode of the fourteenth transistor M214 may be connected to a gate electrode of the twelfth transistor M212. Further, the first electrode and the gate electrode of the fourteenth transistor M214 are connected to each other and may be diode-connected. Therefore, since the fourteenth transistor M214 has a mirroring relationship with the twelfth transistor M212, when a current flows in the twelfth transistor M212, a current also flows in the fourteenth transistor M214 and thus the current charged in a parasitic capacitor of the thirteenth transistor M213 may be discharged.

Further, the feedback unit 240 may include a fifteenth transistor M215 and a sixteenth transistor M216. A first electrode of the fifteenth transistor M215 may be connected to the first power source Vcc and a second electrode thereof may be connected to the second power source Vss. Further, the gate electrode of the fifteenth transistor M215 may be connected to a gate electrode of the twelfth transistor M212 of the current sensing unit 230. Therefore, the fifteenth transistor M215 may perform a switching operation depending on the voltage of the gate electrode of the twelfth transistor M212. That is, the feedback unit 240 may perform the switching operation depending on a voltage of a fourth node N24. Further, a second capacitor C22 may be connected between the first electrode and the gate electrode of the fifth transistor M215. A first electrode of the sixteenth transistor M216 may be connected to the first power source Vcc and a second electrode thereof may be connected to the second node N22 of the level shifter 210. Further, the gate electrode of the sixteenth transistor M216 may be connected to the first electrode of the fifteenth transistor M215.

As the result, the feedback unit 240 may control the voltage of the second node N22 of the level shifter 210 in response to the voltage output from the current sensing unit 230. When the feedback unit 240 having the above exemplary configuration receives a predetermined voltage from the current sensing unit 230, the second node N22 of the level shifter 210 may be connected to the first power source Vcc.

Here, the first power source Vcc may have a voltage level in a high state and the second power source Vss may have a voltage level in a low state lower than that of the first power source Vcc. Further, the first power source Vcc may be 7V and the second power source Vss may be a ground.

Further, the first transistor M21 and the second transistor M22, the ninth transistor M29 and the tenth transistor M210, the twelfth transistor M212, the fourteenth transistor M214, and the fifteenth transistor M215 may be illustrated as an N MOS transistor and the third transistor M23 to the eighth transistor M28, the eleventh transistor M211, the thirteenth transistor M213, and the sixteenth transistor M216 are illustrated as a P MOS transistor, but the exemplary embodiment of the present invention is not limited thereto. Further, the first electrodes and the second electrodes of each transistor may be source electrodes and drain electrodes.

An exemplary operation of the gate driver 200 having the above configuration will be described in detail with reference to FIGS. 3 and 4.

Referring to FIG. 4, the gate driver 200 may receive the first control signal control1 and the second control signal control2. The first control signal control1 may be in the high state in the first section T21 and a low state in the second section T22. Further, the second control signal control2 may be in the low state in the first section T21 and the high state in the second section T22. Further, the first control signal control1 and the second control signal control2 are each repeated in the high state and the low state. FIG. 4 illustrates that lengths of the first section T11 and the second section T12 are the same, but the exemplary embodiment of the present invention is not limited thereto.

In the first section T21, the first control signal control1 may be in the high state and the second control signal control2 may be in the low state. The first transistor M21 may be turned on and the second transistor M22 may be turned off, by the first control signal control1 and the second control signal control2. When the first transistor M21 is turned on, the first node N21 is connected to the second power source Vss and thus the first node N21 may be in a low state. Further, when the first node N21 is in the low state, the gate electrode of the fourth transistor M24 is in the low state and thus the fourth transistor M24 may be turned on. When the fourth transistor M24 is turned on, since the second transistor M22 is in the turned off state, the second node N22 may be in the high state. When the second node N22 is in the high state, the gate electrode of the third transistor M23 is in the high state and thus the third transistor M23 may be turned off. Further, the gate electrode of the fifth transistor M25 is applied with a voltage in a low state by the voltage of the first node N21 and thus the fifth transistor M25 may be turned on. Further, the gate electrode of the sixth transistor M26 is in the high state and thus the sixth transistor M26 may be turned off. That is, in the first section T21, the first node N21 of the level shifter 210 may be in the low state and the second node N22 thereof may be in the high state.

Further, in the second section T22, the first control signal control1 may be in the low state and the second control signal control2 may be in the high state. When the first control signal control1 is in the low state and the second control signal control2 is in the high state, the first transistor M21 may be turned off and the second transistor M22 may be turned on. When the first transistor M21 is turned off, the first node N21 may be in the high state. Further, when the first node N21 is in the high state, the gate electrode of the fourth transistor M24 is in the high state and thus the fourth transistor M24 may be turned off. When the fourth transistor M24 is turned off, since the second transistor M22 is in the turned on state, the second node N22 may be in the low state. When the second node N22 is in the low state, the gate electrode of the third transistor M23 is in the low state and thus the third transistor M23 may be turned on. Further, the second electrode and the gate electrode of the fifth transistor M25 are in a high state and thus the fifth transistor M25 may be turned off. Further, the second electrode and the gate electrode of the sixth transistor M26 is in the low state and thus the sixth transistor M26 may be turned on. That is, in the first section T22, the first node N21 of the level shifter 210 may be in the high state and the second node N22 thereof may be in the low state.

Further, in the first section T21, the first node N21 is in the low state and the second node N22 is in the high state, such that the seventh transistor M27 of the output switch unit 220 may be turned on and the eighth transistor M28 thereof may be turned off. Therefore, a current I_{B} may flow from the first power source Vcc to the output terminal out, and thus the first capacitor C21 connected to the output terminal out may be charged. Further, in the second section T22, the first node N21 is in the high state and the second node N22 is in the low state, such that the seventh transistor M27 of the output switch unit 220 may be turned off and the eighth transistor M28 thereof may be turned on. Therefore, the first power source Vcc is not connected to the output terminal out and thus a current may no longer flow. Further, when the eighth transistor M28 is in a turn on state, a current may flow from the first power source Vcc to the second power source Vss through the eighth transistor M28. In this case, the first electrode and the gate electrode of the tenth transistor M210 have the same voltage level, such that the tenth transistor M210 may be turned on and a current I_{A} may flow from the first power source Vcc to the second power source Vss. Further, since the ninth transistor M29 has a mirroring relationship with the tenth transistor M210, when the tenth transistor M210 is turned on and thus the current I_{A} flows, the ninth transistor M29 is also turned on and thus a current may flow. Therefore, the current charged in the first capacitor C11 may be discharged through the ninth transistor M29. Therefore, the first section T21 may be called a charging section and the second section T22 may be called a discharging section.

Further, in the first section T21, the first node N21 is in the low state and the second node N22 is in the high state, such that the thirteenth transistor M213 may be turned on and the eleventh transistor M211 may be turned off. In the first section T21, the eleventh transistor M211 may be turned off and thus a current may not flow in the thirteenth transistor M213 and the fourteenth transistor M214. Further, in the second section T12, the first node N11 may be in the high state and the second node N12 is in the low state, such that the eleventh transistor M211 may be turned on and the thirteenth transistor M213 may be turned on. When the eleventh transistor M211 is turned on, the twelfth transistor M212 may be diode-connected, and therefore the current may flow in the eleventh transistor M211 and the twelfth transistor M212. When the current flows from the first electrode of the twelfth transistor M212 to the second electrode thereof, the gate electrode of the twelfth transistor M212 may have the voltage level in the high state.

Further, when the gate electrode of the twelfth transistor M212 has the voltage level in the high state, the gate electrode of the fifteenth transistor M215 of the feedback unit 240 may have the voltage level in the high state and thus the fifth transistor M215 may be turned on in the second section T22. Therefore, current may flow from the first electrode of the fifteenth transistor M215 to the second electrode thereof. In this case, the second capacitor C22 may be connected between the first electrode and the gate electrode of the fifteenth transistor M215 and the voltage between the first electrode and the gate electrode of the fifteenth transistor M215 may be constantly kept due to the second capacitor C22, such that current may stably flow from the first electrode of the fifteenth transistor M215 to the second electrode thereof. When current flows from the first electrode of the fifteenth transistor M215 to the second electrode thereof, the gate electrode of the sixteenth transistor M216 of the feedback unit 240 may have the voltage level in the low state. The second node N22 is applied with the voltage level of the first power source Vcc by the sixteenth transistor M216 and thus the second node N22 may keep the voltage level in the high state. Therefore, the gate electrode of the eighth transistor M28 of the output switch unit 220 may be the voltage level in the high state in the second section T22. When the gate electrode of the eighth transistor M28 attains the voltage level in the high state, the voltage difference between the first electrode and the gate electrode of the eighth transistor M28 is reduced and thus the current flowing from the first electrode of the eighth transistor M28 to the second electrode thereof may be reduced. Therefore, the amount of current flowing through the eighth transistor M28 and the tenth transistor M210 in the second section T22 is reduced and thus the power consumption of the gate driver 200 may be reduced.

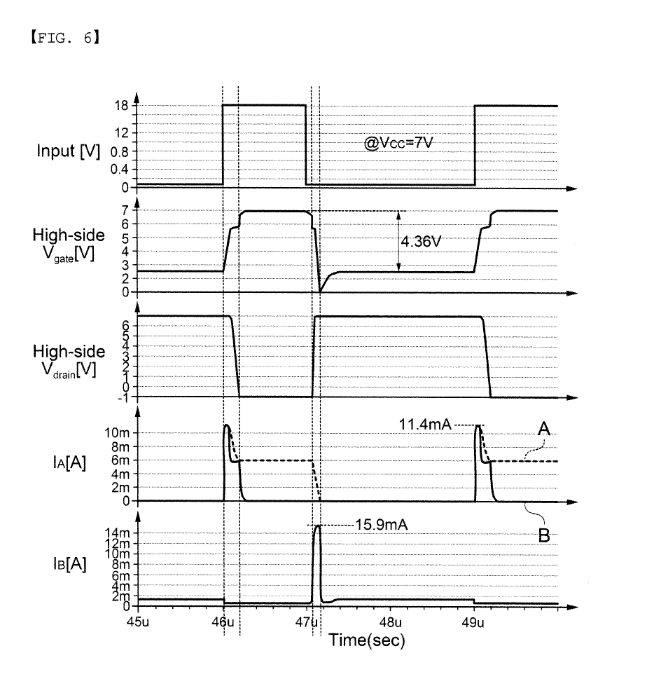

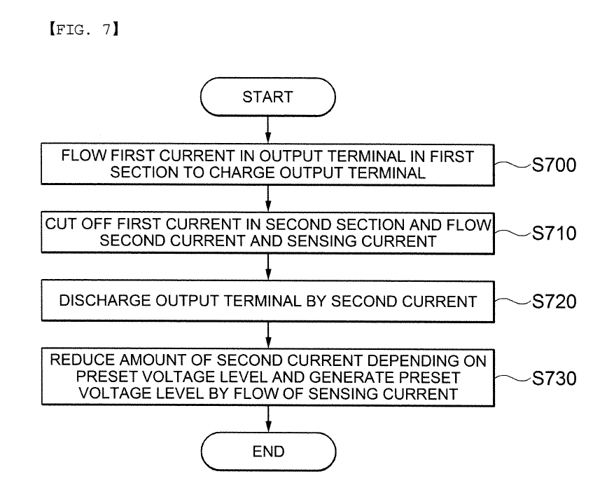

FIG. 5 is a block diagram illustrating that the gate driver illustrated in FIG. 3 is connected to a power switch and FIG. 6 is a simulation timing diagram of a driving of a gate driver in the state in which the gate driver is connected to the power switch.

Referring to FIG. 5, the gate driver 200 is connected to a power switch 500 and may be operated by being applied with the first control signal control1 and the second control signal control2 as illustrated in FIG. 4. In this case, the second control signal control2 may be input in the high state and the first control signal control1 may be input by inverting the second control signal control2 and thus only the second control signal is illustrated. The second control signal may be at a voltage between 0V and 1.8V. In the power switch 500, a high side transistor M31 and a low side transistor M32 may be connected to each other in series. Further, a gate electrode of the high side transistor M31 is connected to the gate driver 200, and a gate of the low side transistor M32 is connected to a signal to turn off the low side transistor M32 and thus the low side transistor M32 may be in a turn off state.

Referring to FIG. 6, when a voltage (input) of the second control signal control2 is in the high state, the gate driver performs a discharging operation and a voltage applied to the gate electrode of the high side transistor M31 is converted into a high-side Vgate. In this case, since the high side transistor M31 and the low side transistor M32 are in a turn off state, a high-side Vdrain of the high side transistor M31 may drop to a low state. In this case, the gate driver 200 is operated as a discharging section and the current I_{A} flowing in the eighth transistor M28 and the tenth transistor M210 of FIG. 3 may start to flow. In this case, the current I_{A} may charge a parasitic capacitor which is formed in the eighth transistor M28 and the tenth transistor M210 and thus a large amount of current flows initially and then charges the parasitic capacitor and then the amount of current I_{A} may be reduced stepwise. In this case, the voltage applied to the gate electrode of the eighth transistor M28 is converted into the first power source Vcc by the sixteenth transistor M216 and thus it may be appreciated that the magnitude of current I_{A} which is a very small amount like B flows. On the other hand, in the case of the gate driver 100 illustrated in FIG. 1, it may be appreciated that the amount of current flowing in the eighth transistor M18 and the tenth transistor M10 is slightly reduced like A then flows. Further, when the voltage (input) of the second control signal is in the low state, the gate driver 200 is in the charging state and the first current I_{B} flows and thus may charge the parasitic capacitor which is formed in the high side transistor M31.

FIG. 7 is a flow chart illustrating a method for driving a gate driver including a level shifter illustrated in FIG. 3.

Referring to FIGS. 3 and 7, a method for driving a gate driver including a level shifter may charge the output terminal out by causing the first current I_{B} to flow in the first section (S700). To this end, the output switch unit 220 is connected to the output terminal out and may charge the output terminal out by making the causing first current flow in the output terminal out. Further, the first current I_{B} may be cut off in the second section and the second current I_{A} and the sensing current may flow (S710). In this case, the second current I_{A} may flow in the output switch unit 220 and the sensing current may flow in the current sensing unit 230. Further, paths through which the first current I_{B} and the second current flow are different from each other and therefore the second current I_{A} may not be transferred to the output terminal out. Further, the output terminal out may be discharged by the second current I_{A} (S720). Further, the amount of second current I_{A} is reduced depending on the preset voltage level and the preset voltage level may be generated by the flow of the sensing current (S730).

According to the exemplary embodiment of the present invention, when the output terminal out is discharged, the current discharged from the output terminal out may be mirrored with the second current I_{A}.

According to the exemplary embodiments of the present invention, the gate driver including a level shifter and the method for driving the same may reduce the amount of constant current which is unnecessarily generated in the gate driver. Therefore, it is possible to reduce the power consumption of the gate driver.

The functions of various elements illustrated in the drawings of exemplary embodiments of the present invention may be provided by using hardware which may be associated with proper software to execute the software and dedicated hardware. When performed by a processor, the function may be provided by a single dedicated processor, a single sharing processor, or a plurality of individual processors which may be partially shared.

In claims of the present specification, elements expressed as a unit for performing specific functions includes any method of performing a specific function and these elements may include a combination of circuit elements performing the specific function or any type of software including a firmware, a microcode, and the like which are coupled with circuits suitable to perform software for performing the specific functions.

In the present specification, ‘one embodiment’ of principles of the present invention and various changes of the expression means that specific features, structures, characteristics, and the like, associated with the embodiment are included in at least one embodiment of the principle of the present invention. Therefore, the expression ‘on embodiment’ and any other modification examples disclosed throughout the present specification do not necessarily mean the same embodiment.

The designation of various changes of expressions such as “connected” and “connecting”, and the like in the present specification means that one element may be connected directly to or coupled directly to another element or be connected to or coupled to another element, having the other element intervening therebetween. Unless explicitly described to the contrary, a singular form includes a plural form in the present specification. In addition, components, steps, operations, and/or elements mentioned in the present specification do not exclude the existence or addition of one or more other components, steps, operations, and/or elements.

What is claimed is:

1. A gate driver, comprising:
a level shifter outputting a first signal and a second signal;
an output switch unit causing a first current flow in an output terminal by a voltage of the first signal in a first section to charge the output terminal, causing a a second current flow by a voltage of the second signal in a second section, and discharging the output terminal depending on the second current;
a current sensing unit causing a sensing current flow depending on the voltage of the second signal in the second section and outputting a preset voltage depending on the flow of the sensing current; and
a feedback unit causing the voltage of the second signal to attain a preset level or more in the second section depending on the preset voltage.

2. The gate driver according to claim 1, wherein the level shifter is connected between a first power source and a second power source and determines the voltage of the first signal and the voltage of the second signal, respectively, depending on a first control signal and a second control signal.

3. The gate driver according to claim 1, wherein the level shifter includes: a first transistor performing a switching operation depending on a first control signal and determining a voltage level of a first node, a second transistor performing a switching operation depending on a second control signal and determining a voltage level of a second node, a third transistor performing a switching operation depending on the voltage of the first node and transferring first power to the first node, a fourth transistor performing a switching operation depending on the voltage of the second node and transferring the first power to the second node, a fifth transistor diode-connected depending on the voltage of the first node, and a sixth transistor diode-connected depending on the voltage of the second node.

4. The gate driver according to claim 1, wherein the output terminal is discharged by a current mirrored with the second current.

5. The gate driver according to claim 3, wherein the output switch unit includes: a seventh transistor performing a switching operation depending on the voltage of the first node and turned on in the first section to charge the output terminal, an eighth transistor performing the switching operation to discharge a current charged in the output terminal in the second section, a ninth transistor performing the switching operation depending on the voltage of the second node and turned on in the second section, and a tenth transistor diode connected when the ninth transistor is turned on to flow a current so as to turn on the eighth transistor.

6. The gate driver according to claim 5, wherein the current sensing unit includes an eleventh transistor performing the switching operation depending on the voltage of the second node and turned on in the second section and a twelfth transistor receiving a current from the eleventh transistor in response thereto to be diode-connected.

7. The gate driver according to claim 6, wherein the current sensing unit includes a thirteenth transistor performing the switching operation depending on the voltage of the first node and turned on in the first section and a fourteenth transistor connected to the thirteenth transistor and turned on depending on a gate voltage of the twelfth transistor.

8. The gate driver according to claim 7, wherein the feedback unit includes a fifteenth transistor turned on depending on the predetermined voltage and a sixteenth transistor turned on to change the voltage level of the second node when the fifteenth transistor is turned on.

9. The gate driver according to claim 8, wherein a capacitor is further connected between a first electrode and a gate electrode of the fifteenth transistor.

10. A method for driving a gate driver, comprising:
causing a first current flow in an output terminal in a first section to charge the output terminal;
cutting off the first current in a second section and causing a second current flow and a sensing current flow;
discharging the output terminal by the second current; and
reducing an amount of the second current depending on a preset voltage level and generating the preset voltage level by flow of the sensing current.

11. The method according to claim 10, wherein in the discharging of the output terminal, the current discharged from the output terminal flows, mirrored with the second current.

12. A gate driver, comprising:
a level shifter configured for outputting a first signal and a second signal;
an output switch configured for producing a first output current in response to the first signal to charge an output terminal, producing a second current in response to the second signal, and discharging the output terminal depending on the second current;
a current sensing unit configured for producing a sensing current depending on a magnitude of the second signal and outputting a prescribed voltage based on the sensing current; and
a feedback circuit configured for controlling the magnitude of the second signal to attain a prescribed magnitude or greater based on the prescribed voltage.

13. A method for driving a gate driver, comprising the steps of:
causing flow of a first current to charge an output terminal;
terminating the first current flow, and causing flow of a second current and a sensing current;
discharging the output terminal using the second current flow mirrored with the first current; and
reducing the second current based on a preset voltage level produced in response to the sensing current.
